(19) United States
(12) Patent Application Publication
(10) Pub. No.: US 2022/0238508 A1
(43) Pub. Date: Jul. 28, 2022

(54) VERTICAL DEVICE HAVING A REVERSE SCHOTTKY BARRIER FORMED IN AN EPITAXIAL SEMICONDUCTOR LAYER FORMED OVER A SEMICONDUCTOR SUBSTRATE

(71) Applicant: Silergy Semiconductor Technology (Hangzhou) Ltd., Hangzhou (CN)

(72) Inventors: Fei Yao, Hangzhou (CN); Shijun Wang, Hangzhou (CN); Dengping Yin, Hangzhou (CN)

(21) Appl. No.: 17/720,262

(22) Filed: Apr. 13, 2022

Related U.S. Application Data
(63) Continuation-in-part of application No. 16/850,230, filed on Apr. 16, 2020.
Application No. 16/850,230 is a continuation of application No. 15/496,271, filed on Apr. 25, 2017, now abandoned.

(30) Foreign Application Priority Data
Apr. 25, 2016 (CN) 201610263857.1

(51) Int. Cl. H01L 27/02; H01L 29/861; H01L 27/08; H01L 29/06; H01L 29/66; H01L 29/872; H02H 9/04

(52) U.S. Cl. CPC H01L 27/0248; H01L 29/861; H01L 27/0255; H01L 27/0814; H01L 29/0649; H01L 29/866; H01L 29/66136; H01L 29/66143; H01L 29/8613; H01L 29/872; H02H 9/046; H01L 29/0692

(57) ABSTRACT

Disclosed is a vertical device, an ESD protection device having the vertical device, and a method for manufacturing the vertical device. The vertical device includes a forward diode which is formed by a semiconductor substrate and an epitaxial semiconductor layer, and a reverse Schottky barrier between an anode metal and the epitaxial semiconductor layer. The vertical device has a vertical current path from a second electrode to a first electrode, and a lateral current distribution at least partially surrounded and limited by the reverse Schottky barrier. The reverse Schottky barrier reduces the parasitic capacitance of the diode at high voltages, thereby increasing the response speed of the ESD protection device at high voltages.

### CROSS-REFERENCE TO RELATED APPLICATION

This application is a continuation-in-part of U.S. application Ser. No. 16/850,230 filed on Apr. 16, 2020, which published as U.S. 2020/0243501 A1, on Jul. 30, 2020, which will be abandoned, and is a continuation application of U.S. application Ser. No. 15/496,271 filed on Apr. 25, 2017, which was abandoned, and claims the benefit of Chinese Patent Application No. 201610263857.1, filed on Apr. 25, 2016, the contents of which are incorporated herein by reference in their entireties.

### BACKGROUND OF THE DISCLOSURE

### Technical Field

The present disclosure relates to a semiconductor device and a method for manufacturing the same, and in particular, to a vertical device, a method for manufacturing the vertical device and an ESD protection device.

### Background of the Disclosure

Electrostatic discharge (ESD) is a phenomenon that release and transfer charge between integrated circuit chips and external objects. Due to a large amount of charge being released in a short time, ESD energy is much higher than the chip's bearing capacity, which may result in temporary failure or even permanent damage of the chip function. During the process for manufacturing a chip, a bracelet or anti-static clothing can be used to reduce ESD damage. The chip having been manufactured is easily affected by ESD between the chip and the external objects when it is used in various different environments. Therefore, an ESD protection device is provided in the chip to offer an electrostatic discharge path for effectively protecting the chip, and the reliability and service life of the integrated circuit chip are improved.

In modern electronic products such as smartphones, laptops, tablets and LED displays, ESD protection devices are widely used for providing protection to high-speed data ports mounted on printed circuit boards (PCBs), for example, HDMI, USB, DVI. These ESD protection devices are either discrete devices or integrated into the chip. In order to protect the high-speed data ports, the ESD protection devices should have high response speed. The response speed of an ESD protection device is mainly influenced by its own capacitance. In order to increase the response speed, the capacitance of the ESD protection device is preferably set to be less than 0.5 pF. Further, the ESD protection device should also have a high electrostatic discharge capability.

The ESD protection device can be implemented based on various circuit structures. FIG. 1 shows a schematic circuit structure of an ESD protection device. The ESD protection device includes a Zener diode DZ and a rectification diode D1 coupled in series between the input-output terminal I/O and the ground GND. The input-output terminal I/O is, for example, a terminal of high-speed data ports. When the ESD protection device is turned off, the input-output terminal I/O is used to transfer data. When electrostatic charge is discharged, the Zener diode DZ and the rectification diode D1 are both turned on and the ESD protection device is turned on, thereby providing an electrostatic discharge path. FIG. 2 shows an equivalent circuit of the parasitic capacitance of the ESD protection device shown in FIG. 1. In the ESD protection device, the parasitic capacitance of the Zener diode DZ and the rectification diode D1 are denoted by CZ and C1, respectively. Since the Zener diode DZ and the rectification diode D1 are coupled in series with each other, the equivalent capacitance C(I/O−GND) of the ESD protection device is equal to C1*CZ/(C1+CZ). The parasitic capacitance C1 of the rectification diode D1 is much smaller than the equivalent capacitance CZ of the Zener diode CZ, which can significantly reduce the parasitic capacitance of the ESD protection device, for example, by two to three orders of magnitude.

The equivalent capacitance C(I/O−GND) of the above ESD protection device is influenced by the voltage V(I/O−GND) across the ESD protection device. As the voltage V(I/O−GND) increases, the equivalent capacitance C(I/O−GND) increases rapidly. As a result, the response speed of the ESD protection device is significantly reduced at high voltages.

Therefore, it is desirable to further reduce the equivalent capacitance of the ESD protection device at high voltages so that the response speed could be improved.

### SUMMARY OF THE DISCLOSURE

In view of above, the disclosure provides a vertical device, a method for manufacturing the vertical device, and an ESD protection device. A reverse Schottky barrier is formed in the cathode of the vertical device to reduce the parasitic capacitance of the diode at high voltages, thereby increasing the response speed of the ESD protection device at high voltages.

According to a first aspect of the disclosure, there is provided a vertical device, comprising: a semiconductor substrate with a doping type of P-type; an epitaxial semiconductor layer with a doping type of N-type and located on said semiconductor substrate; a first doped region with a doping type of N-type and located in said epitaxial semiconductor layer; an anode metal which is formed on said epitaxial semiconductor layer and electrically coupled to said first doped region; a first electrode being formed on an insulating layer located on said epitaxial semiconductor layer, and said first electrode being electrically coupled to said first doped region and said anode metal; and a second electrode being formed on a surface of said semiconductor substrate opposite to said epitaxial semiconductor layer, wherein a forward diode for current rectification is formed by said semiconductor substrate and said epitaxial semiconductor layer, a reverse Schottky barrier is formed between said anode metal and said epitaxial semiconductor layer, and said vertical device has a vertical current path from said second electrode to said first electrode, and a lateral current distribution at least partially surrounded and limited by said reverse Schottky barrier.

Preferably, said vertical device has a first equivalent resistance which is an interface resistance between said epitaxial semiconductor layer and said first doping region.

Preferably, said reverse Schottky barrier is equivalent to a second equivalent capacitor and a second equivalent resistor which are coupled in series with said first equivalent resistance.

Preferably, said a forward diode for current rectification is formed by said semiconductor substrate and said epitaxial semiconductor layer.

Preferably, doping concentration of said first doped region is larger than that of said epitaxial semiconductor layer.

Preferably, said anode metal has a strip structure adjacent to said first doped region.

Preferably, said anode metal has a ring-like structure surrounding said first doped region.

Preferably, the vertical device further comprises: an isolation structure which extends from a surface of said epitaxial semiconductor layer into said semiconductor substrate for defining an active region of said vertical device.

Preferably, said reverse Schottky barrier is formed in said active region.

Preferably, said isolation structure is a doped region of P-type or a trench isolation.

According to a second aspect of the disclosure, there is provided an ESD protection device, comprising: the above-identified vertical device; and a Zener diode, wherein said first doped region of said vertical device is coupled to a cathode of said Zener diode.

Preferably, said semiconductor substrate of said vertical device is coupled to an input-output terminal, and an anode of said Zener diode is coupled to ground.

According to a third aspect of the disclosure, there is provided a method for manufacturing a vertical device, comprising: forming an epitaxial semiconductor layer on a semiconductor substrate, said semiconductor substrate and said epitaxial semiconductor layer are respectively of P-type and of N-type; forming a first doped region in said epitaxial semiconductor layer, said first doped region is of N-type; forming an anode metal on said epitaxial semiconductor layer and electrically coupled to said first doped region; forming a first electrode on an insulating layer located on said epitaxial semiconductor layer, and said first electrode being electrically coupled to said first doped region and said anode metal; and forming a second electrode on a surface of said semiconductor substrate opposite to said epitaxial semiconductor layer, wherein a forward diode for current rectification is formed by said semiconductor substrate and said epitaxial semiconductor layer, a reverse Schottky barrier is formed between said anode metal and said epitaxial semiconductor layer, and said vertical device has a vertical current path from said second electrode to said first electrode, and a lateral current distribution at least partially surrounded and limited by said reverse Schottky barrier.

Preferably, after said step of forming an epitaxial semiconductor layer, the method further comprises: forming an isolation structure which extends from a surface of said epitaxial semiconductor layer into said semiconductor substrate for defining an active region of said vertical device.

The vertical device according to the present disclosure has a vertical current path through the forward diode from the second electrode to the first electrode. Moreover, the reverse Schottky barrier is electrically coupled between the second electrode and the first electrode. Thus, the forward diode and the reverse Schottky barrier are reversely biased in the vertical current path, when a forward voltage is applied between the second electrode and the first electrode.

When a first equivalent capacitance of the forward diode changes with the voltage and a second equivalent capacitance of the reverse Schottky barrier changes with the voltage, the changed values of the first equivalent capacitance and the second equivalent capacitance are at least partially cancelled off. Thus, the vertical device has an effect of suppressing variation of the equivalent capacitance at high voltages by the reverse Schottky barrier.

Furthermore, the vertical device according to the present disclosure has a lateral current distribution at least partially surrounded by the reverse Schottky barrier. When a forward voltage is applied between the second electrode and the first electrode, the reverse Schottky barrier is reversely biased, and a depletion region is formed below the reverse Schottky barrier and has an effect of limiting the lateral current distribution of the forward diode. As the interface resistance between the first doped region and the epitaxial semiconductor layer is large, the capacitance parameter of the vertical device is equivalent to the series connection of the first equivalent capacitance and the second equivalent capacitance, and the first equivalent capacitance of the forward diode is reduced due to improved lateral current distribution of the forward diode. The changed values of the first equivalent capacitance and the second equivalent capacitance are largely cancelled off. Thus, the vertical device has an improved effect of suppressing variation of the equivalent capacitance at high voltages by the reverse Schottky barrier.

The equivalent capacitance C(I/0−GND) of the ESD protection device shows reduced changes with the voltage, so that it can provide low capacitance and high response speed at high voltages.

### BRIEF DESCRIPTION OF THE DRAWINGS

The above and other objects, advantages and features of the present disclosure will become more fully understood from the detailed description given hereinbelow in connection with the appended drawings, and wherein:

FIG. 1 shows a schematic circuit structure of an ESD protection device;

FIG. 2 shows an equivalent circuit of the parasitic capacitance of the ESD protection device shown in FIG. 1;

FIGS. 3a and 3b are respectively a perspective diagram and a cross sectional diagram of a vertical device according to a first embodiment of the present disclosure;

FIGS. 4a and 4b are a perspective diagram and a cross sectional diagram of a vertical device according to a second embodiment of the present disclosure;

FIG. 5 is a structural diagram of an ESD protection device according to a third embodiment of the present disclosure;

FIG. 6 is a structural diagram of an ESD protection device according to a fourth embodiment of the present disclosure;

FIG. 7 is a structural diagram which shows a simulated current distribution of a vertical device in an ESD protection device according to the third embodiment of the present disclosure;

FIG. 8 is a structural diagram which shows a simulated current distribution of a vertical device in an ESD protection device according to the fourth embodiment of the present disclosure;

FIG. 9 is an equivalent circuit diagram of an ESD protection device according to an embodiment of the present disclosure;

FIG. 10 shows a CV curve of an ESD protection device according to the prior art and a CV curve of an ESD protection device according to an embodiment of the present disclosure; and

FIGS. 11a to 11f are cross sectional diagrams at different steps of the method for manufacturing an ESD protection device according to a fifth embodiment of the present disclosure.

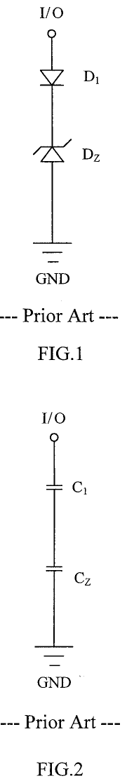

### DETAILED DESCRIPTION OF THE DISCLOSURE

Exemplary embodiments of the present disclosure will be described in more details below with reference to the accompanying drawings. In the drawings, like reference numerals denote like members. The figures are not drawn to scale, for the sake of clarity. Moreover, some well-known parts may not be shown. For simplicity, the structure of the semiconductor device having been subject to several relevant process steps may be shown in one figure.

It should be understood that when one layer or region is referred to as being “above” or “on” another layer or region in the description of device structure, it can be directly above or on the other layer or region, or other layers or regions may be intervened therebetween. Moreover, if the device in the figures is turned over, the layer or region will be “under” or “below” the other layer or region.

In contrast, when one layer is referred to as being “directly on” or “on and adjacent to” or “adjoin” another layer or region, there are not intervening layers or regions present. In the present application, when one region is referred to as being “directly in”, it can be directly in another region and adjoins the another region, but not in a implantation region of the another region.

In the present application, the term “semiconductor structure” means generally the whole semiconductor structure formed at each step of the method for manufacturing the semiconductor device, including all of the layers and regions having been formed.

Some particular details of the present disclosure will be described below, such as exemplary semiconductor structures, materials, dimensions, process steps and technologies of the semiconductor device, for better understanding of the present disclosure. However, it can be understood by one skilled person in the art that these details are not always essential for but can be varied in a specific implementation of the disclosure.

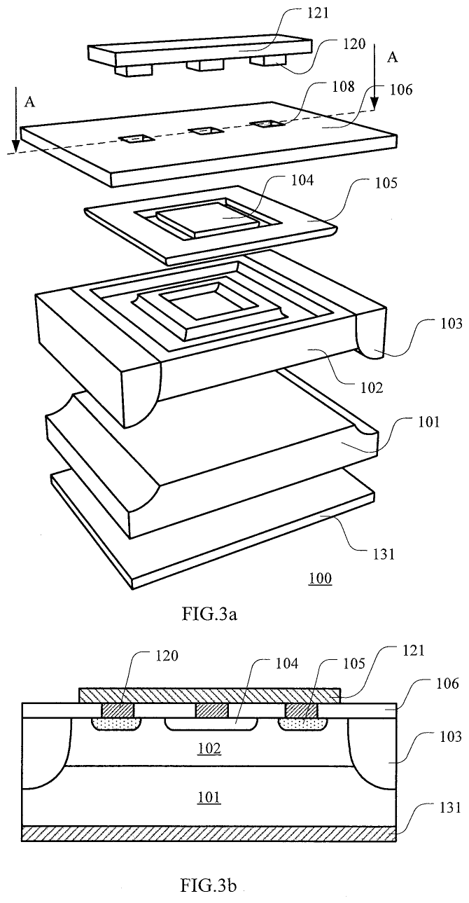

FIGS. 3a and 3b are respectively a perspective diagram and a cross sectional diagram of a vertical device according to a first embodiment of the present disclosure. The FIG. 3b is a cross sectional diagram taken along line AA in FIG. 3a.

As shown in FIGS. 3a and 3b, the vertical device 100 includes a semiconductor substrate 101, an epitaxial semiconductor layer 102 located on the semiconductor substrate 101, a first doped region 104 and a second doped region 105 located in the epitaxial semiconductor layer 102. The semiconductor substrate 101 and the epitaxial semiconductor 102 are respectively of P-type and of N-type, the first doped region 104 and the second doped region 105 are respectively of N-type and of P-type.

In the embodiment, the second doped region 105 is a ring-like structure surrounding the first doped region 104.

In the vertical device 100, a first PN junction is formed between the epitaxial semiconductor layer 102 and the semiconductor substrate 101, a second PN junction is formed between the epitaxial semiconductor layer 102 and the second doped region 105, so that the second PN junction is reversely biased over the first PN junction. The semiconductor substrate 101 is used as an anode, and the epitaxial semiconductor layer 102 is used as a cathode. Therefore, the second PN junction is located in the cathode of the vertical device 100.

In the embodiment, the first doped region 104 is heavily doped over the epitaxial semiconductor layer 102, the second doped region 105 has a doping concentration similar with that of the semiconductor substrate 101, or the second doped region 105 is heavily doped over the semiconductor substrate 101. For example, the peak value of the doping concentration of the semiconductor substrate 101 is not less than 1e18 atoms/cm3, preferably, more than 1e19 atoms/cm3, to reduce the intrinsic resistance of the diode. The peak value of the doping concentration of the epitaxial semiconductor layer 102 is about 1e13˜1e16 atoms/cm3, preferably, less than 1e14 atoms/cm3, to reduce the parasitic capacitance of the diode. The peak value of the doping concentration of the first doped region 104 is about 1e18˜1e21 atoms/cm3. The peak value of the doping concentration of the second doped region 105 is about Ie19˜1e21 atoms/cm30.

Preferably, the vertical device 100 further includes an isolation structure 103. The isolation structure 103 extends from the surface of the epitaxial semiconductor layer 102 to the semiconductor substrate 101 at the periphery of the vertical device 100, thereby defining an active region of the vertical device 100. The isolation structure 103 for example is a trench isolation or a doped region. If the isolation structure 103 is a doped region, it is of p-type. The PN junction between the doped region and epitaxial semiconductor layer may be used to define the lateral flow of current because they have opposite doping types.

Preferably, the vertical device 100 further includes an insulating layer 106 located on the epitaxial semiconductor layer 102. A first electrode 121 is formed on the insulating layer 106. The first electrode 121 is electrically coupled to the first doped region 104 and the second doped region 105 via a conductive channel 120 penetrating the insulating layer 106, so that the first doped region 104 and the second doped region 105 are coupled to each other. A second electrode 131 is formed on the surface of the semiconductor substrate 101 opposite to the epitaxial semiconductor layer 102. The first electrode 121 and the second electrode 131 are made of, for example, a metal material selected from the group consisting of gold, silver and copper or an alloy thereof.

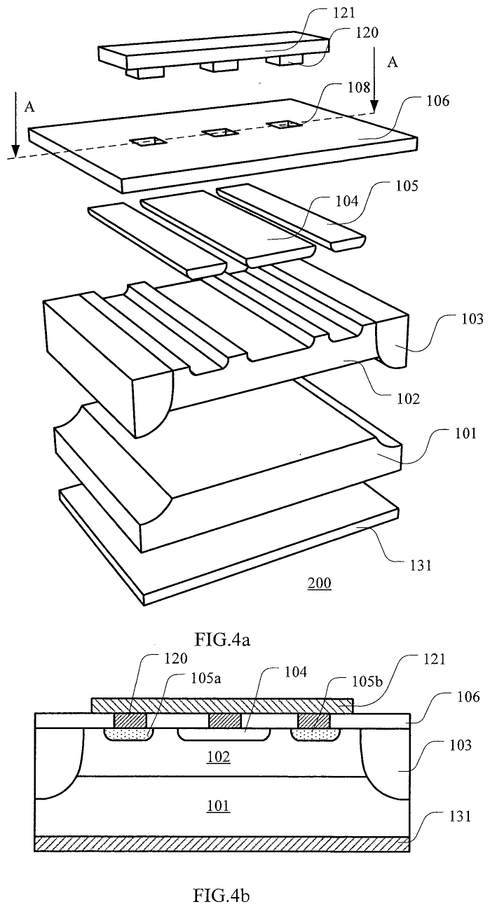

FIGS. 4a and 4b are respectively a perspective diagram and a cross sectional diagram of a vertical device according to a second embodiment of the present disclosure. The FIG. 4b is a cross sectional diagram taken along line AA in FIG. 4a.

The difference between the vertical device 200 according to the second embodiment and the vertical device 100 according to the first embodiment is that the second doped region in the vertical device 200 is a strip structure adjacent to the first doped region 104, rather than a ring-like structure. Preferably, the vertical device 200 includes two second doped regions 105a and 105b. The first electrode 121 is electrically coupled to the first doped region 104 and the two second doped regions 105a and 105b via the conductive channel 120 penetrating the insulating layer 106, so that the first doped region 104 and the two second doped region 105a and 105b are coupled together.

Other aspects of the vertical device 200 according to the second embodiment are the same as those of the vertical device 100 according to the first embodiment and they will not be repeated here.

FIG. 5 shows a structural diagram of an ESD protection device according to a third embodiment of the present disclosure.

As shown in FIG. 5, the ESD protection device 300 includes a vertical device 310 and a Zener diode 320 coupled in series between the input-output terminal I/O and the ground GND. The input-output terminal I/O is, for example, a terminal of high-speed data ports. When the ESD protection device 300 is turned off, the input-output terminal I/O is used to transfer data. When electrostatic charge is released, the vertical device 310 and the Zener diode 320 are both turned on and the ESD protection device 300 is turned on, thereby providing an electrostatic discharge path.

The structure of the vertical device 310 is the same as that of the vertical device 200 according to the second embodiment as shown in FIGS. 4a and 4b.

In the vertical device 310, the epitaxial semiconductor layer 102 is of a doping type opposite to that of the semiconductor layer 101, and the first PN junction is formed between them. The epitaxial semiconductor layer 102 is of a doping type opposite to that of the second doped regions 105a and 105b, and two second PN junctions are formed between them.

The epitaxial semiconductor layer 102 is a common layer used by the first PN junction and the two second PN junctions, so the two second PN junctions are both reversely biased over the first PN junction. The semiconductor substrate 101 is used as an anode, and the epitaxial semiconductor layer 102 is used as a cathode. The first PN junction may be equivalent to the PN junction of the first diode D1. The two second PN junctions are located in the cathode of the first diode D1, respectively equivalent to the PN junctions of the two second diodes Dp1 and Dp2. In addition, the first doped region 104 is of the same doping type as of the epitaxial semiconductor layer 102, and the interface resistance between them is equivalent to the resistance R.

The Zener diode 320 may be of a conventional structure and of a conventional doping concentration, which includes the semiconductor substrate 201 with a doping type of P-type and the doped region 202 with a doping type of N-type. They are used as an anode and a cathode of the Zener diode 320, respectively. A first electrode 221 and the doped region 202 are electrically coupled with each other, a second electrode 231 is electrically coupled to the interface of the semiconductor substrate 201 opposite to the doped region 202.

If the vertical device 310 and the Zener diode 320 respectively form separate semiconductor devices, the two devices may be electrically coupled by a bonding wire.

The second electrode 131 of the vertical device 310 is used as the input-output terminal I/O, the second electrode 231 of the Zener diode 320 is used as the ground GND.

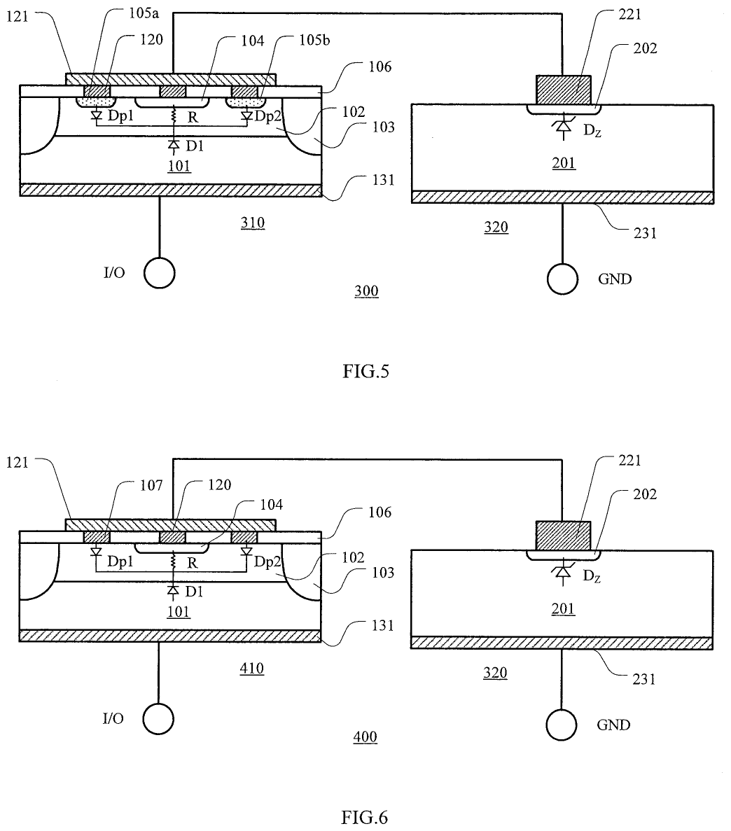

FIG. 6 is a structural diagram of an ESD protection device according to a fourth embodiment of the present disclosure.

As shown in FIG. 6, the ESD protection device 400 includes a vertical device 410 and a Zener diode 320 coupled in series between the input-output terminal I/O and the ground GND. The input-output terminal I/O is, for example, a terminal of high-speed data ports. When the ESD protection device is turned off, the input-output terminal I/O is used to transfer data. When the electrostatic charge is released, the vertical device 410 and Zener diode 320 are both turned on and the ESD protection device 400 is turned on, thereby providing an electrostatic discharge path.

The difference between the vertical device 410 and the vertical device 200 according to the second embodiment is that the vertical device 410 omits the second doped region 105 and the conductive channel is replaced by the anode metal 107. In addition, the first electrode 121 is electrically coupled to the first doped region 104 via a conductive channel 120 penetrating the insulating layer 106, and the first electrode 121 contacts the anode metal 107, so that the first doped region 104 and the anode metal 107 are coupled together.

In the vertical device 410, the epitaxial semiconductor layer 102 is of a doping type opposite to that of the semiconductor layer 101, and the first PN junction is formed between them. Two Schottky barriers are formed between the epitaxial semiconductor layer 102 and the anode metal 107. The epitaxial semiconductor layer 102 is a common layer used by the first PN junction and the two Schottky barriers, so the two Schottky barriers are both reversely biased over the first PN junction. The semiconductor substrate 101 is used as an anode, and the epitaxial semiconductor layer 102 is used as a cathode. The first PN junction may be equivalent to the PN junction of the first diode D1. The two Schottky barriers are located in the cathode of the first diode D1, which are respectively equivalent to the Schottky barriers of the two second diodes Dp1 and Dp2. In addition, the first doped region 104 is of the same doping type as that of the epitaxial semiconductor layer 102, and the interface resistance between them is equivalent to the resistor R.

The Zener diode 320 may be of a conventional structure and of a conventional doping concentration, which includes the semiconductor substrate 201 with a doping type of P-type and the doped region 202 with a doping type of N-type. They are used as an anode and cathode of the Zener diode 320, respectively. A first electrode 221 and the doped region 202 are electrically coupled to each other, a second electrode 231 is electrically coupled to the interface of the semiconductor substrate 201 opposite to the doped region 202.

If the vertical device 410 and the Zener diode 320 respectively form separate semiconductor devices, the two devices can be electrically coupled by a bonding wire.

The second electrode 131 of the vertical device 410 is used as the input-output terminal I/O, the second electrode 231 of the Zener diode 320 is used as the ground GND.

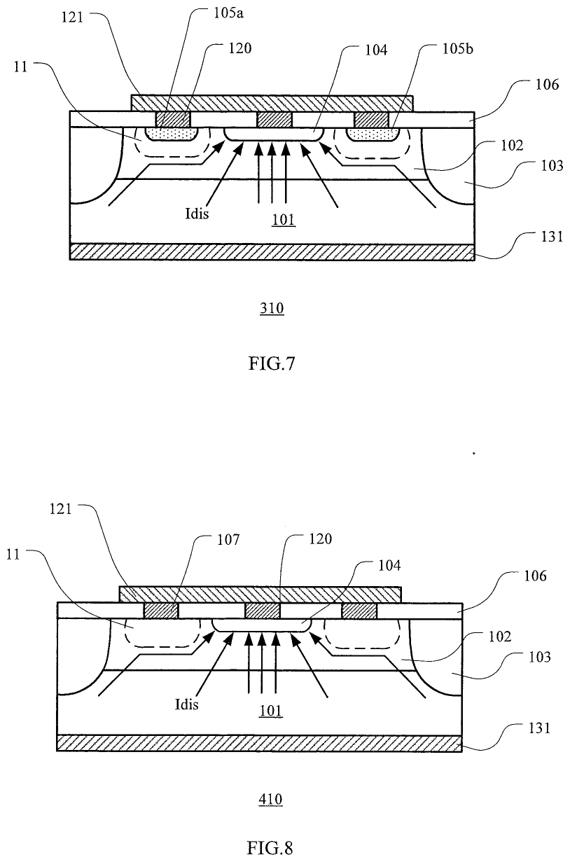

FIGS. 7 and 8 are structural diagrams with simulated current distribution of vertical devices in ESD protection devices according to the third embodiment and the fourth embodiments of the present disclosure, respectively.

FIG. 7 shows a vertical device 310 having a first diode D1 and two second diodes Dp1 and Dp2, which are two reverse diodes surrounding a forward diode. FIG. 8 shows a vertical device 410 having a first diode D1 and two second diodes Dp1 and Dp2, which are two reverse Schottky barriers surrounding a forward diode. Both the vertical devices 310 and 410 have similar structures and similar simulation results, and only the simulation result of the vertical device 410 will be described in detail.

The vertical device 410 has a vertical current path Idis through the forward diode from the second electrode 131 to the first electrode 121. Moreover, the reverse Schottky barrier is electrically coupled between the second electrode 131 and the first electrode 121. Thus, the forward diode and the reverse Schottky barrier are reversely biased in the vertical current path Idis, when a forward voltage is applied between the second electrode 131 and the first electrode 121.

When a first equivalent capacitance of the forward diode changes with the voltage and a second equivalent capacitance of the reverse Schottky barrier changes with the voltage, the changed values of the first equivalent capacitance and the second equivalent capacitance are at least partially cancelled off. Thus, the vertical device 410 has an effect of suppressing variation of the equivalent capacitance at high voltages by the reverse Schottky barrier.

Furthermore, the vertical device 410 according to the present disclosure has a lateral current distribution at least partially surrounded by the reverse Schottky barrier. When a forward voltage is applied between the second electrode 131 and the first electrode 121, the reverse Schottky barrier is reversely biased, and a depletion region 11 is formed below the reverse Schottky barrier and has an effect of limiting the lateral current distribution of the forward diode. As the interface resistance between the first doped region and the epitaxial semiconductor layer is large, the capacitance parameter of the vertical device is equivalent to the series connection of the first equivalent capacitance and the second equivalent capacitance, and the first equivalent capacitance of the forward diode is reduced due to improved lateral current distribution of the forward diode. The changed values of the first equivalent capacitance and the second equivalent capacitance are largely cancelled off. Thus, the vertical device 410 has an improved effect of suppressing variation of the equivalent capacitance at high voltages by the reverse Schottky barrier.

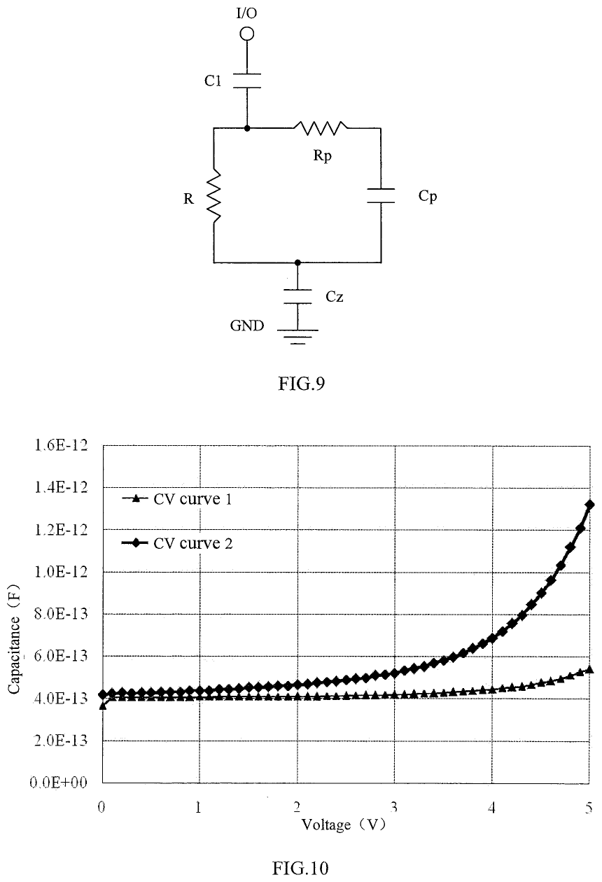

FIG. 9 is an equivalent circuit diagram of an ESD protection device according to an embodiment of the present disclosure. As shown in FIG. 9, in the ESD protection device 300, the vertical device 310 has the first diode D1 which can be equivalent to a first equivalent capacitor C1, the resistance R which can be equivalent to a first equivalent resistor R, and two second diodes Dp1 and Dp2 which can be equivalent a serial circuit of a second equivalent capacitor Cp and a second equivalent resistor Rp. The Zener diode 320 can be equivalent to a third capacitor CZ.

If the resistance R, the second equivalent capacitance Cp and the second equivalent resistance Rp of the vertical device 310 are taken as the parasitic impedance Zp, Zp is equal to R when Cp=0, and Zp represents capacitive reactance when Cp>0 and Rp>0.

If the resistance R is large, C(I/0−GND)=C1*Cp*Cz/(ClCp+ClCz+CpCz). The two second diodes Dp1 and Dp2 are reversely biased over the first diode D1, so, when the first equivalent capacitance C1 of the first diode D1 changes with the voltage and the second equivalent capacitance Cp of the two second diodes Dp1 and DP2 changes with the voltage, the change values are at least partially cancelled off.

FIG. 8 shows a CV curve of an ESD protection device according to the prior art and a CV curve of an ESD protection device according to an embodiment of the present disclosure, where CV curve 1 represents a typical CV curve of an ESD protection device according to an embodiment of the present disclosure, CV curve 2 is a typical CV curve of the vertical device according to the prior art.

By comparing the CV curve 1 with the CV curve 2, it is found that the parasitic capacitance of the vertical device according to the present disclosure is significantly reduced with the voltage variation rate. When the voltage changes in a range of 0V to 5V, the variation rate of the equivalent capacitance of the vertical device according to the prior art is 230%, but the variation rate of the equivalent capacitance of the ESD protection device according to the present disclosure is about 37.5%.

Thus, the ESD protection device 310 according to the embodiment of the present disclosure uses a reverse PN junction formed in the cathode to suppress the variation of the equivalent capacitance at high voltages. The equivalent capacitance C(I/O−GND) of the ESD protection device 300 shows reduced changes with the voltages, so that it can provide low capacitance and high response speed at high voltages.

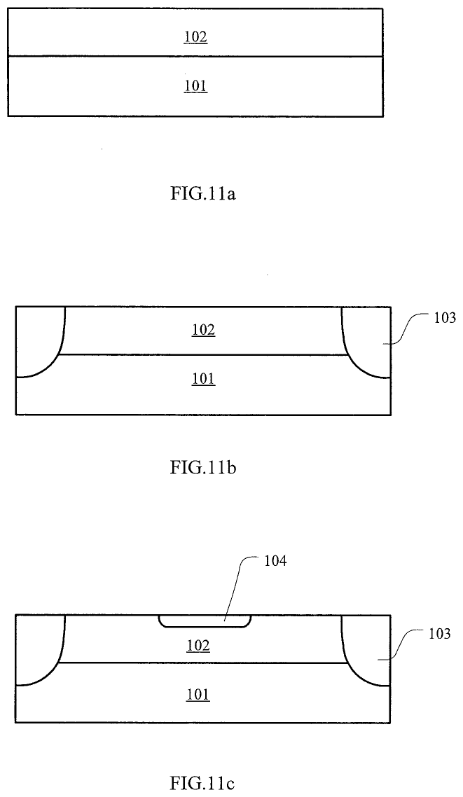

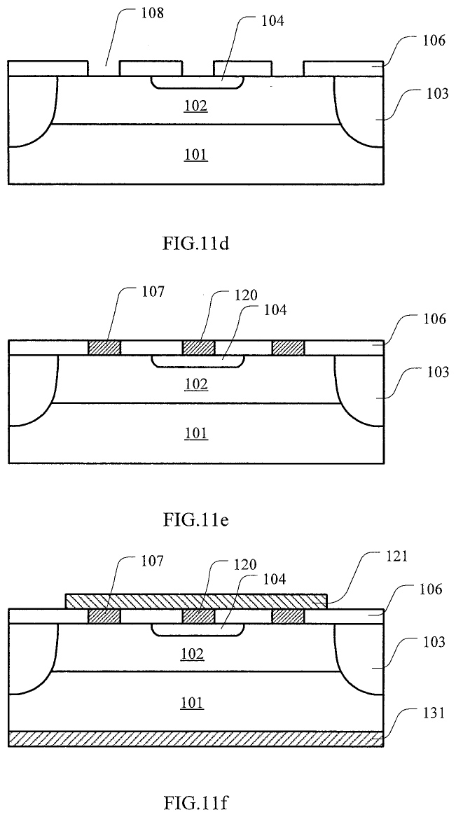

FIGS. 11a to 11f show cross sectional diagrams at different steps of the method for manufacturing an ESD protection device according to the fifth embodiment of the present disclosure. The method is used to manufacture an ESD protection device according to the first embodiment.

As shown in FIG. 11a, the epitaxial semiconductor layer 102 is epitaxially grown on the surface of the semiconductor substrate 101 by a known deposition process. The deposition process is, for example, one selected from the group consisting of electron beam evaporation (EBM), chemical vapor deposition (CVD), atomic layer deposition (ALD), and pulsation. The epitaxial semiconductor layer has a thickness, for example, 3˜10 μm.

The semiconductor substrate 101 is, for example, a single-crystal substrate and doped to be of P-type. The peak value of the doping concentration of the semiconductor substrate 101 is not less than 1e18 atoms/cm3, preferably, more than 1e19 atoms/cm3. The epitaxial semiconductor layer 102 is doped to be of N-type. The peak value of the doping concentration of the epitaxial semiconductor layer 102 is about 1e17˜1e18 atoms/cm3.

A P-type semiconductor layer or region may be formed by implanting a P-type dopant such as B in the semiconductor layer or region. An N-type semiconductor layer or region may be formed by implanting an N-type dopant such as P or As in the semiconductor layer or region. By controlling implantation parameters, such as implantation energy and dosage, the doped region may reach a predetermined depth and may have a predetermined doping concentration.

Further, an isolation structure 103 is formed for defining an active region of the vertical device, as shown in FIG. 11b. The isolation structure 103 for example is a doped region.

The isolation structure 103 extends from the surface of the epitaxial semiconductor layer 102 to the semiconductor substrate 101 at the periphery of the vertical device, for isolating the ESD protection device from the adjacent semiconductor devices. The PN junction between the doped region and epitaxial semiconductor layer is used to define the lateral flow of current because they are of opposite doping types.

In this step, a photoresist layer is formed on a surface of the epitaxial semiconductor layer 102, and then patterned by lithography to be a photoresist mask. The photoresist mask includes an opening that exposes a portion of the surface of the epitaxial semiconductor layer 102. The ion implantation is carried out via the opening of the photoresist mask by conventional ion implantation and driving-in process to form the isolation structure 103. Then, the photoresist mask is removed by ashing or dissolution with a solvent.

In an alternative embodiment, the isolation structure 103 may be a trench isolation and formed in any step subsequent to the step of forming the epitaxial semiconductor layer 102. The process to form a trench isolation is known in the art, for example, it includes etching a shallow trench in a semiconductor structure and filling the shallow trench with insulating materials.

Further, the first doped region 104 is formed in the epitaxial semiconductor layer 102, as shown in FIG. 11c. The first doped region 104 is of N-type, extending from the surface of the epitaxial semiconductor layer 102 to a predetermined depth of the epitaxial semiconductor layer 102. The peak value of the doping concentration of the first doped region 104 is about 1e18˜1e21 atoms/cm3.

In this step, a photoresist layer is formed on a surface of the epitaxial semiconductor layer 102, and then patterned by lithography to be a photoresist mask. The photoresist mask includes an opening that exposes a portion of the surface of the epitaxial semiconductor layer 102. The ion implantation is carried out via the opening of the photoresist mask by conventional ion implantation and driving-in process to form the first doped region 104. Then, the photoresist mask is removed by ashing or dissolution with a solvent.

Next, the interlayer insulating layer 106 is formed on the corresponding surface of the epitaxial semiconductor layer by the above conventional deposition processes. For example, the interlayer insulating layer 106 is made of silicon oxide. Then, the openings are formed in the interlayer insulating layer 106 by photolithography and etching, which expose surfaces of the first doped region 104 and the epitaxial semiconductor layer 102, respectively, as shown in FIG. 11d.

Then, the anode metal 107 and the conductive channel 120 are formed in the opening of the interlayer insulating layer 106 by the above known deposition processes and the planarization process (e.g., chemical mechanical planarization), as shown in FIG. 11e. The anode metal 107 and the conductive channel 120 are made of, for example, a metal material selected from the group consisting of gold, silver and copper.

In the embodiment, the anode metal 107 is a ring-like structure surrounding the first doped region 104.

Then, the first electrode 121 is formed on the surface of the interlayer insulating layer 106, and the second electrode 131 is formed on the surface of the semiconductor substrate 101 opposite to the epitaxial semiconductor layer 102 as shown in FIG. 11f. The first electrode 121 and the second electrode 131 are made of, for example, a metal material selected from the group consisting of gold, silver and copper.

It should also be understood that the relational terms such as “first”, “second”, and the like are used in the context merely for distinguishing one element or operation form the other element or operation, instead of meaning or implying any real relationship or order of these elements or operations. Moreover, the terms “comprise”, “comprising” and the like are used to refer to comprise in nonexclusive sense, so that any process, approach, article or apparatus relevant to an element, if follows the terms, means that not only said element listed here, but also those elements not listed explicitly, or those elements inherently included by the process, approach, article or apparatus relevant to said element. If there is no explicit limitation, the wording “comprise a/an . . . ” does not exclude the fact that other elements can also be included together with the process, approach, article or apparatus relevant to the element.

Although various embodiments of the present disclosure are described above, these embodiments neither present all details, nor imply that the present disclosure is limited to these embodiments. Obviously, many modifications and changes may be made in light of the teaching of the above embodiments. These embodiments are presented and some details are described herein only for explaining the principle of the disclosure and its actual use, so that one skilled person can practice the present disclosure and introduce some modifications in light of the disclosure. The disclosure is intended to cover alternatives, modifications and equivalents that may be included within the spirit and scope of the disclosure as defined by the appended claims.

1. A vertical device, comprising:
a semiconductor substrate with a doping type of P-type;
an epitaxial semiconductor layer with a doping type of N-type and located on said semiconductor substrate;
a first doped region with a doping type of N-type and located in said epitaxial semiconductor layer;
an anode metal which is formed on said epitaxial semiconductor layer and electrically coupled to said first doped region;
a first electrode being formed on an insulating layer located on said epitaxial semiconductor layer, and said first electrode being electrically coupled to said first doped region and said anode metal; and
a second electrode being formed on a surface of said semiconductor substrate opposite to said epitaxial semiconductor layer,
wherein a forward diode for current rectification is formed by said semiconductor substrate and said epitaxial semiconductor layer, a reverse Schottky barrier is formed between said anode metal and said epitaxial semiconductor layer, and said vertical device has a vertical current path from said second electrode to said first electrode, and a lateral current distribution at least partially surrounded and limited by said reverse Schottky barrier.

2. The vertical device according to claim 1, wherein said vertical device has a first equivalent resistance which is an interface resistance between said epitaxial semiconductor layer and said first doping region.

3. The vertical device according to claim 2, wherein said reverse Schottky barrier is equivalent to a second equivalent capacitor and a second equivalent resistor which are coupled in series with said first equivalent resistance.

4. The vertical device according to claim 1, wherein doping concentration of said first doped region is larger than that of said epitaxial semiconductor layer.

5. The vertical device according to claim 1, wherein said anode metal has a strip structure adjacent to said first doped region.

6. The vertical device according to claim 1, wherein said anode metal has a ring-like structure surrounding said first doped region.

7. The vertical device according to claim 1, further comprising:
an isolation structure which extends from a surface of said epitaxial semiconductor layer into said semiconductor substrate for defining an active region of said vertical device.

8. The vertical device according to claim 7, wherein said reverse Schottky barrier is formed in said active region.

9. The vertical device according to claim 1, wherein said isolation structure is a doped region of P-type or a trench isolation.

10. An ESD protection device, comprising:
said vertical device according to claim 1; and
a Zener diode,
wherein said first doped region of said vertical device is coupled to a cathode of said Zener diode.

11. The ESD protection device according to claim 10, wherein said semiconductor substrate of said vertical device is coupled to an input-output terminal, and an anode of said Zener diode is coupled to ground.

12. A method for manufacturing a vertical device, comprising:
forming an epitaxial semiconductor layer on a semiconductor substrate, said semiconductor substrate and said epitaxial semiconductor layer are respectively of P-type and of N-type;
forming a first doped region in said epitaxial semiconductor layer, said first doped region is of N-type;
forming an anode metal on said epitaxial semiconductor layer and electrically coupled to said first doped region;
forming a first electrode on an insulating layer located on said epitaxial semiconductor layer, and said first electrode being electrically coupled to said first doped region and said anode metal; and
forming a second electrode on a surface of said semiconductor substrate opposite to said epitaxial semiconductor layer,
wherein a forward diode for current rectification is formed by said semiconductor substrate and said epitaxial semiconductor layer, a reverse Schottky barrier is formed between said anode metal and said epitaxial semiconductor layer, and said vertical device has a vertical current path from said second electrode to said first electrode, and a lateral current distribution at least partially surrounded and limited by said reverse Schottky barrier.

13. The method according to claim 12, after said step of forming an epitaxial semiconductor layer, further comprising:
forming an isolation structure which extends from a surface of said epitaxial semiconductor layer into said semiconductor substrate for defining an active region of said vertical device.
